(19) United States
(12) Patent Application Publication
(10) Pub. No.: US 2019/0259923 A1
(43) Pub. Date: Aug. 22, 2019

(54) LIGHT-EMITTING DEVICE

(71) Applicant: EPISTAR CORPORATION, Hsinchu (TW)

(72) Inventors: Shih-An Liao, Hsinchu (TW); Ming-Chi Hsu, Hsinchu (TW); Min-Hsun Hsieh, Hsinchu (TW)

(21) Appl. No.: 15/902,451

(22) Filed: Feb. 22, 2018

(51) Int. Cl. H01L 33/50; H01L 33/60; H01L 33/62; H01L 21/027; G02B 5/00

(52) U.S. Cl. CPC H01L 33/508; H01L 33/60; G02F 1/13; H01L 21/0274; G02B 5/003; H01L 33/62

(57) ABSTRACT

A light emitting device includes a light-emitting chip; a first light-transmitting layer formed on the light-emitting chip and has two side surfaces; and a first reflective layer formed on the light transmitting layer and extends beyond the two side surfaces of the light-transmitting layer.

### TECHNICAL FIELD

The present disclosure relates to a light-emitting device and in particular to a light-emitting device comprising a reflective layer formed on a wavelength conversion layer.

### DESCRIPTION OF THE RELATED ART

The light-emitting diodes (LEDs) have the characteristics of low power consumption, long operational life, small volume, quick response and stable opto-electrical property of emitted light. Recently, the light-emitting diodes gradually are used in a backlight unit of a liquid crystal display.

In a conventional direct-lit backlight unit, a lens is usually used to shape the light of a light-emitting device with lambertian pattern into a batwing emission pattern. The lens has a certain thickness which applied adversely in a thin display device.

### SUMMARY OF THE DISCLOSURE

A light emitting device includes a light-emitting chip; a first light-transmitting layer formed on the light-emitting chip and has two side surfaces; and a first reflective layer formed on the light transmitting layer and extends beyond the two side surfaces of the light-transmitting layer.

The following description illustrates embodiments and together with drawings to provide a further understanding of the disclosure described above.

### BRIEF DESCRIPTION OF THE DRAWINGS

FIG. 1A is a perspective view of the light-emitting device in accordance with an embodiment of the present disclosure.

FIG. 1B is a cross-sectional view of a light-emitting device taken along line I-I of FIG. 1A

FIG. 1C shows a diagram of measuring the light-emitting device of FIG. 1A.

FIG. 1D shows a diagram of measuring the light-emitting device at P1 shown in FIG. 1C.

FIG. 1E shows a diagram of measuring the light-emitting device at P2 shown in FIG. 1C.

FIG. 1F shows a diagram of measuring the light-emitting device at P3 shown in FIG. 1C.

FIG. 1G shows a relationship curve between luminous intensity and angle measured from the light-emitting device of FIG. 1A.

FIG. 2A is a perspective view of the light-emitting device in accordance with an embodiment of the present disclosure.

FIG. 2B is a cross-sectional view of a light-emitting device taken along line I-I of FIG. 2A

FIGS. 3A˜3F are cross-sectional views of making a light-emitting devices in accordance with an embodiment of the present disclosure.

FIGS. 4A˜4F are top views of FIGS. 3A˜3F, respectively.

FIG. 5 is a cross-sectional view of a light-emitting device in accordance with an embodiment of the present disclosure.

FIGS. 6A˜6G are cross-sectional views of making a light-emitting device in accordance with an embodiment of the present disclosure.

FIG. 7A shows a cross-sectional view of a light-emitting device mounting on a carrier with a diffuse-reflection surface in accordance with an embodiment of the present disclosure.

FIG. 7B shows a cross-sectional view of a light-emitting device mounting on a carrier with a light-absorbing surface in accordance with an embodiment of the present disclosure.

FIG. 7C shows a cross-sectional view of a light-emitting device mounting on a carrier with a specular-reflection surface in accordance with an embodiment of the present disclosure.

FIG. 8A shows a simulation result of a relationship curve between luminous intensity and angle measured from the structure of FIG. 7A.

FIG. 8B shows a simulation result of a relationship curve between luminous intensity and angle measured from the structure of FIG. 7B.

FIG. 8C shows a simulation result of a relationship curve between luminous intensity and angle measured from the structure of FIG. 7C.

FIG. 9A is a perspective view of a light-emitting device 400 in accordance with an embodiment of the present disclosure.

FIG. 9B is a top view of FIG. 9A.

FIGS. 10A-10G show cross-sectional views of making a light-emitting device in accordance with an embodiment of the present disclosure.

FIGS. 11A˜11F are cross-sectional views of light-emitting devices in accordance with embodiments of the present disclosure.

FIG. 12A is a cross-sectional view of the light-emitting device of FIG. 2B on a composite carrier in accordance with an embodiment of the present disclosure.

FIG. 12B is a cross-sectional view of the light-emitting device of FIG. 2B on a carrier with two parabolic surfaces in accordance with an embodiment of the present disclosure.

FIG. 12C a relationship curve between luminous intensity and angle measured from the structure of FIG. 12B.

FIG. 13A is a perspective view of a lead frame in accordance with an embodiment of the present disclosure.

FIG. 13B is an exploded view of the light-emitting device of FIG. 2B on the lead frame of FIG. 13A.

FIG. 13C is a cross-sectional view of the light-emitting device of FIG. 2B mounted on the lead frame of FIG. 13A.

FIG. 14 is a perspective view of a lead frame in accordance with an embodiment of the present disclosure.

FIG. 15 shows a cross-sectional view of direct-lit backlight unit of a liquid crystal display in accordance with an embodiment of the present disclosure.

### DETAILED DESCRIPTION OF THE EMBODIMENTS

The drawings illustrate the embodiments of the application and, together with the description, serve to illustrate the principles of the application. The same name or the same reference number given or appeared in different paragraphs or figures along the specification should has the same or equivalent meanings while it is once defined anywhere of the disclosure. The thickness or the shape of an element in the specification can be expanded or narrowed. It is noted that the elements not drawn or described in the figure can be included in the present application by the skilled person in the art.

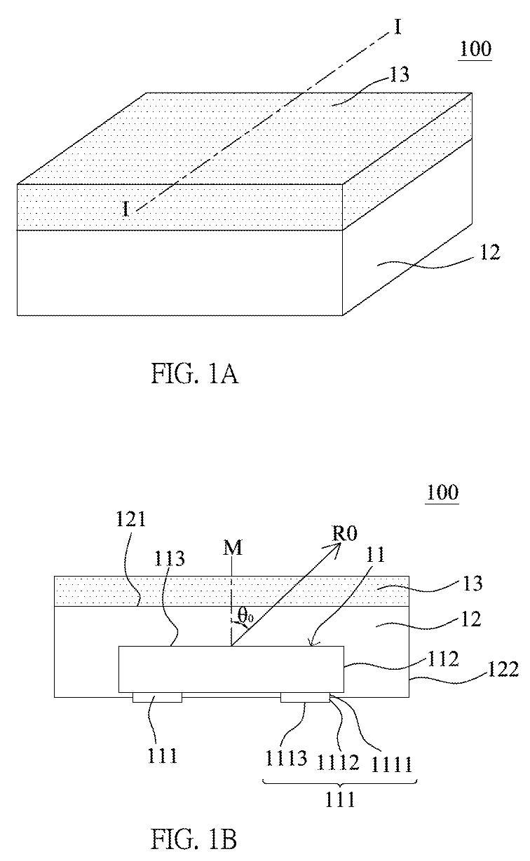

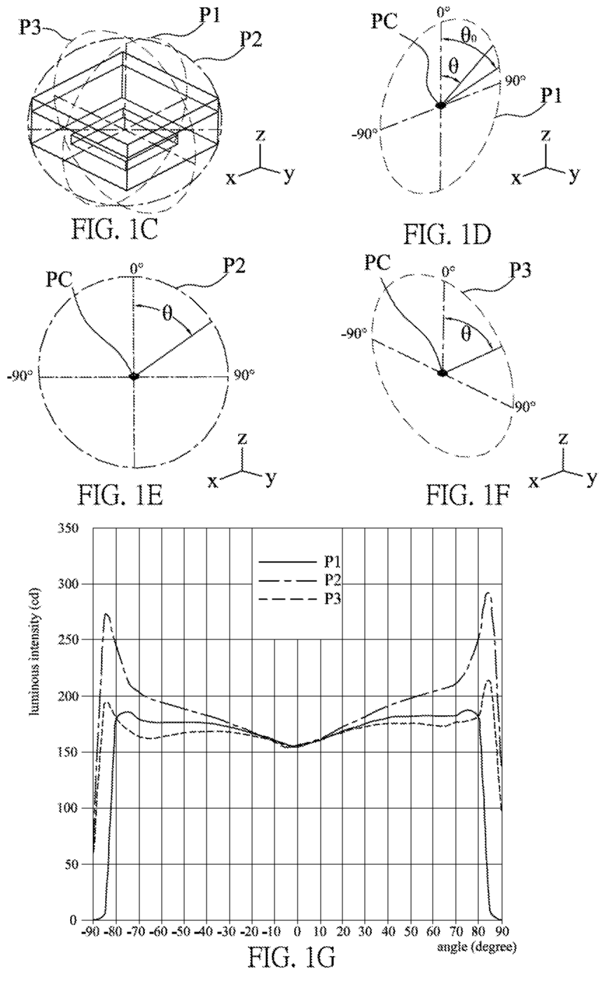

FIG. 1A is a perspective view of a light-emitting device 100 in accordance with an embodiment of the present disclosure. FIG. 1B is a cross-sectional view of the light-emitting device 100 taken along line I-I of FIG. 1A. For simplified illustration, a light-emitting chip 11 is shown as cuboid in FIG. 1B and not shown in FIG. 1A. In appearance, the light-emitting chip 11 may be viewed or not viewed based on the material of a first light-transmitting layer 12.

As shown in FIGS. 1A and 1B, the light-emitting device 100 includes a light-emitting chip 11, a first light-transmitting layer 12 enclosing the light-emitting chip 11, and a first reflective layer 13 formed on a top surface 121 of the first light-transmitting layer 12. The first light-transmitting layer 12 covers four side surfaces 112 and a top surface 113 of the light-emitting chip 11 (two side surfaces are shown in FIG. 1B). The light-emitting chip 11 has two pads 111, each of which has a side surface and a bottom surface 1113 uncovered by the first light-transmitting layer 12. The side surface has a first portion 1111 covered by the first light-transmitting layer 12 and a second portion 1112 uncovered by the first light-transmitting layer 12. The light-emitting chip 11 is mounted on a carrier (not shown) through solder, or an adhesive including a plurality of solder particles mixing with an epoxy resin (for example, anisotropic conductive film or Self Assembly Anisotropic Conductive Paste).

The first reflective layer 13 has a plurality of reflective particles (not shown) mixed in a matrix. The matrix includes silicone-based material or epoxy-based material, and has a refractive index (n) of 1.4˜1.6 or 1.5˜1.6. The reflective particles include titanium dioxide, silicon dioxide, aluminum oxide, zinc oxide, or zirconium dioxide.

In other embodiment, the first reflective layer 13 can be a multilayer for forming a Distributed Bragg Reflector whose material comprising Al₂O₃, SiO₂, TiO₂, Ta₂O₅, or SiNₓ.

FIG. 1C shows a diagram of measuring the light-emitting device 100. In the embodiment, when the light-emitting device 100 emits light, a goniophotometer (for example, the product numbered LP-360B from Light Ports Inc.) is used to measure the luminous intensity of every points on the circle P1, the circle P2 or the circle P3, wherein the circle P1, P2 and P3 are virtual and are defined for measurement. When measuring by the goniophotometer, since the detector is spaced apart the light-emitting device 100 by a distance (at least 20 cm), the light-emitting device 100 can be viewed as a point source and a far field emission pattern is obtained as shown in FIG. 1G. For showing the relative position between the circle P1, P2 or P3 and the light-emitting device 100, the light-emitting device 100 is drawn oversized for clarity in FIG. 1C. On the contrary, the light-emitting device 100 is drawn as a point source and a center point PC in FIGS. 1D-1F.

Furthermore, the angles and the luminous intensities measured at points on the circle are used to plot a graph of luminous intensity distribution curve (for example, FIG. 1G). The luminous intensity of each point on circle P1, P2 or P3 is measured with an angle defined by the included angle (θ) between a first line and a second line, wherein the first line connects one point which is measured on circle P1, P2 or P3 and the center point PC, and the second line is a main axis (Z axis, for example) passing the center point PC and is defined as 0 degree.

FIG. 1D shows a diagram of measuring the light-emitting device 100 at P1. FIG. 1E shows a diagram of measuring the light-emitting device 100 at P2. FIG. 1F shows a diagram of measuring the light-emitting device 100 at P3. As FIGS. 1D˜1F are shown, the 0 degree is located on the Z axis; the +90 degree and −90 degree of circle P1 are located on the X axis, the +90 degree and −90 degree of circle P2 are located on an axis having an angle of 45 degree with respect to the X axis, and the +90 degree and −90 degree of circle P3 are located on the Y axis. The circle P1 locates on the XZ plane and the circle P3 locates on the YZ plane.

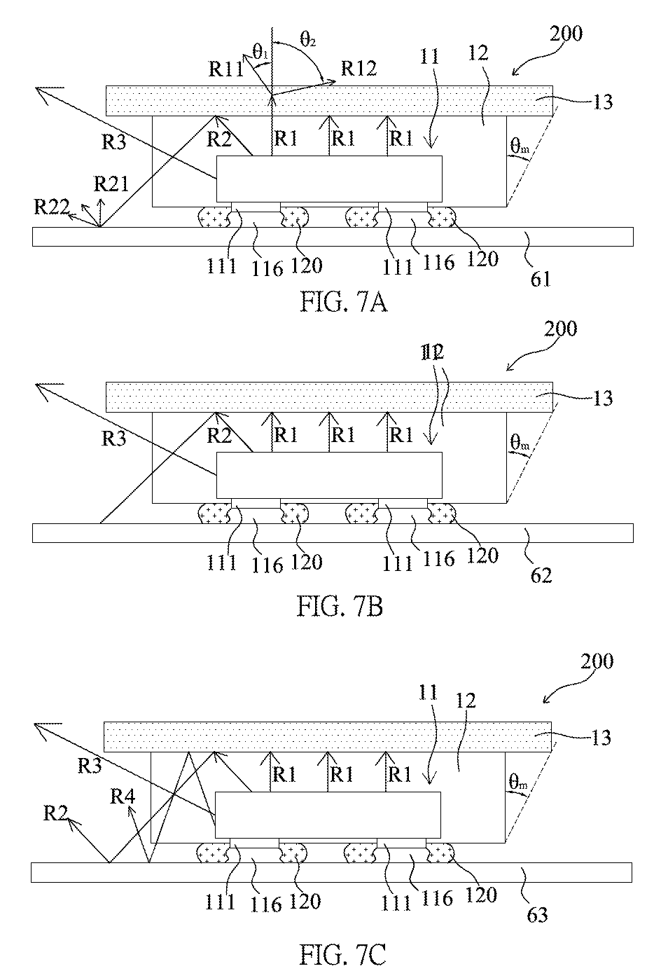

As shown in FIG. 1B, light (for example, R0) emits out of the light-emitting device 100 by an angle (for example, θ₀) with respect to an imaginary line (for example, M) parallel to the side surface 122. As described as FIGS. 1C-1F, the light-emitting device 100 is viewed as a point source (or PC), and when light-emitting device 100 emits light and is measured by goniophotometer, the light (for example, R0) exiting the light-emitting device 100 with an angle (θ₀) regardless of reflecting or scattering by any object (discussed in FIG. 7A) will contribute to the luminous intensity at the included angle (θ₀) on the circle P1, P2 or P3 (θ₀ is only shown in P1). In other words, the included angle is equal to the angle of the light exiting the light-emitting device.

FIG. 1G shows a relationship curve between luminous intensity and angle in a Cartesian coordinate system (x coordinate represents angle; y coordinate represents luminous intensity) transformed from the luminous intensity distribution curve (polar diagram) measured from the circles P1, P2, and P3. For example, for circle P1, the luminous intensity at an included angle of 0° is about 150 cd and the luminous intensity at an included angle of 50° is about 170 cd. The luminous intensity depends on the operating current of the light-emitting device. Basically, the higher the operating current is, the higher the luminous intensity will be.

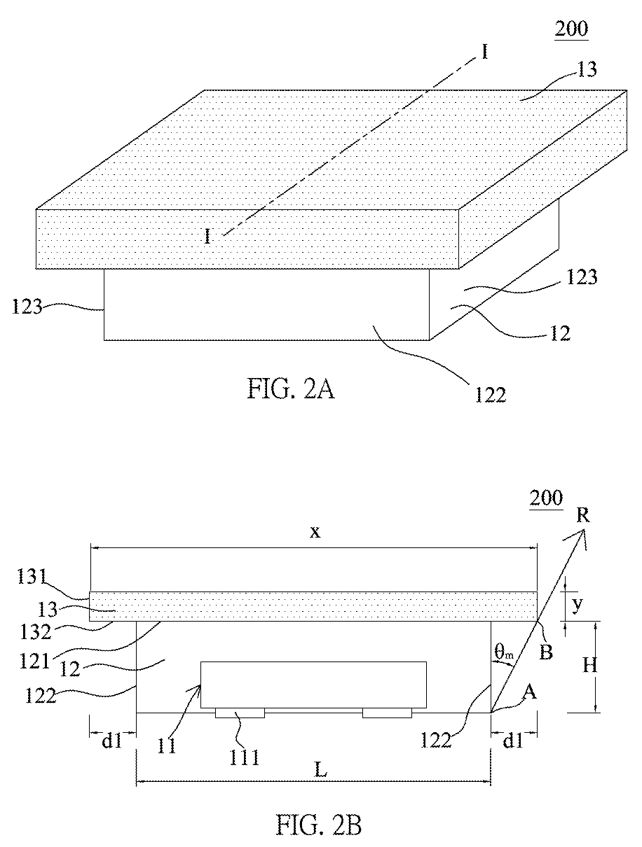

FIG. 2A is a cross-sectional view of a light-emitting device 200 in accordance with an embodiment of the present disclosure. FIG. 2B is a cross-sectional view of the light-emitting device 200 taken along line I-I of FIG. 2A. For simplified illustration, a light-emitting chip 11 is shown as cuboid in FIG. 2B and not shown in FIG. 2A. The light-emitting device 200 has a structure similar to the light-emitting device 100, and devices or elements with similar or the same symbols represent those with the same or similar functions.

The first reflective layer 13 extends beyond two side surfaces 122 of the light-transmitting layer 12 as shown in FIG. 2B, and the first reflective layer 13 extends beyond the other two sides 123 of the first light-transmitting layer 12 shown in FIG. 2A. Specifically, a side surface 131 of the first reflective layer 13 is spaced apart from a side surface 122 by a first distance (d1) and is not flush with the side surface 122. The first reflective layer 13 has a width (x) and a thickness (y). The first light-transmitting layer 12 has a thickness (H) and a width (L). Point A is defined as the lowest point at the side surface 122 and point B is defined as the outermost point at the bottom surface 132 of the first reflective layer 13. A line connecting point A and point B is with respect to a side surface 122 of the first light-transmitting layer 12 by an angle which is defined as a minimum angle (θₘ). d1(=x−L/2), θₘ and H meet the equation I:

$$H * tan {θ}_{m} = d 1 = \frac{x - L}{2} \qquad ( equation I )$$

As described above, likewise, provided the light (R) emits from point A to point B, the light (R) with an angle of (θₘ) will pass out of the light-emitting device 200 and contribute to the luminous intensity at the included angle (θₘ) on the circle P1, P2 or P3 (θₘ is not shown in FIGS. 1D˜1F).

When the light-emitting chip 11 emits light, some light passing outside the first light-transmitting layer 12 touches the first reflective layer 13 and some light passing outside the first light-transmitting layer 12 does not touch the first reflective layer 13 and directly emit out of the light-emitting device 200.

Furthermore, since the first reflective layer 13 extends beyond first light-transmitting layer 12 and is used as a shield, most light will touch the first reflective layer 13 and be reflected by the first reflective layer 13. The light reflected by the first reflective layer 13 will emit out of the light-emitting device 200 until not touching the first reflective layer 13. Basically, light does not touch the first reflective layer 13 and will emit out of the light-emitting device 200 at an angle not less than the minimum angle (θₘ), which contributes to the luminous intensity at the included angle not less than of θₘ. Accordingly, the luminous intensity at the included angle not less than of θₘ is higher than the luminous intensity at the included angle less than of θₘ. The included angle of θₘ is defined as an critical angle (θ_{c}) in the luminous intensity distribution curve.

Referring to equation I, the thickness (H), the width (x) and the width (L) can be designed to determine the minimum angle (θₘ). In other words, by designing the thickness (H) and the width (L) of the first light-transmitting layer 12 and the width (x) of the first reflective layer 13, the minimum angle (θₘ) can be determined and then the critical angle (θ_{c}) is also determined.

Among the light touching the first reflective layer 13, most light is reflected by the reflective layer 13 and less directly pass through the first reflective layer 13. Most of the light directly passing through the first reflective layer 13 will be detected at the angle of 0°˜θₘ (it will be discussed later). The thicker the thickness of the first reflective layer 13 is, the lower the light can pass through the first reflective layer 13, that is lower luminous intensity is measured at the angle of 0°˜θₘ. Accordingly, luminous intensity at angle of 0°˜θₘ can be substantially determined by the thickness (y) of the first reflective layer 13.

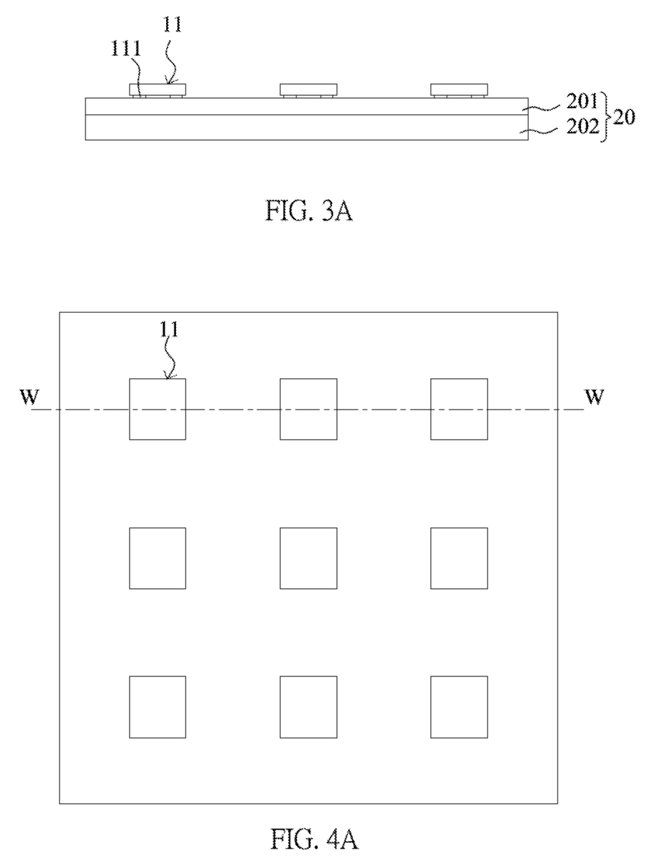

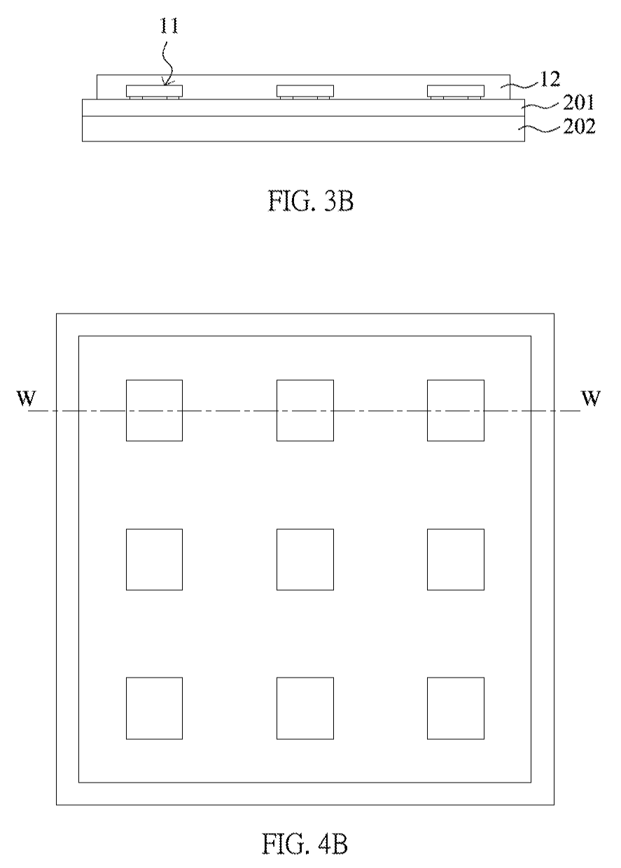

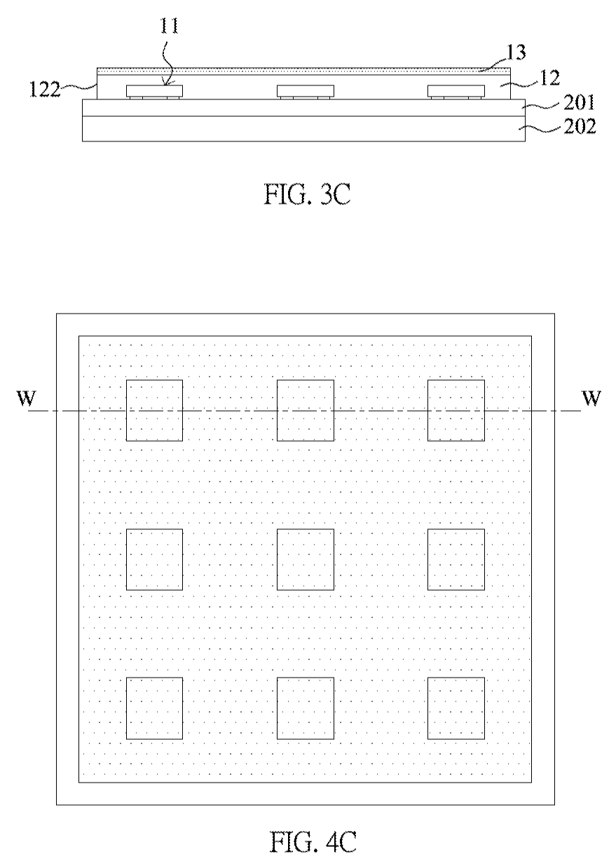

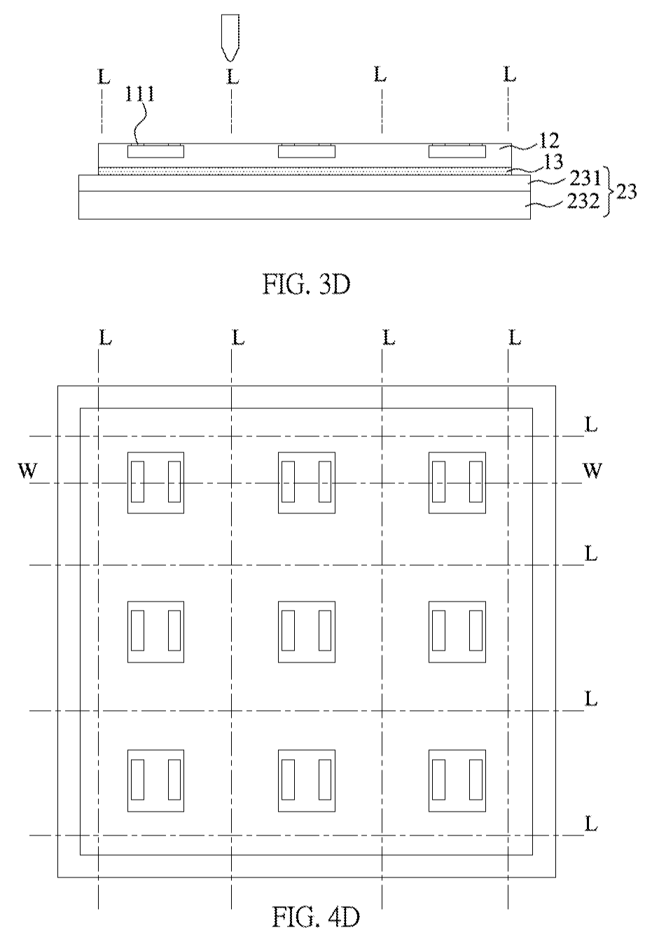

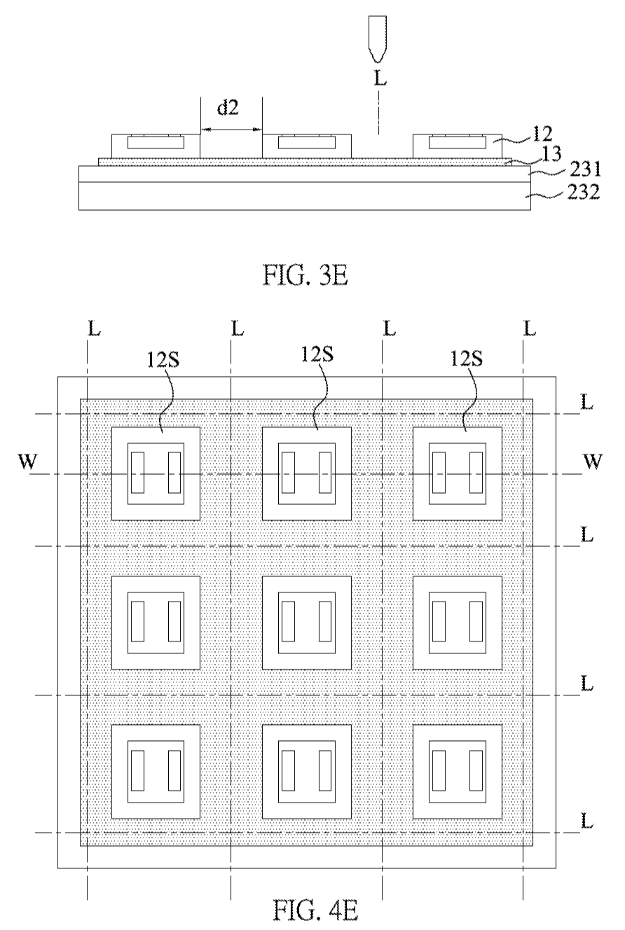

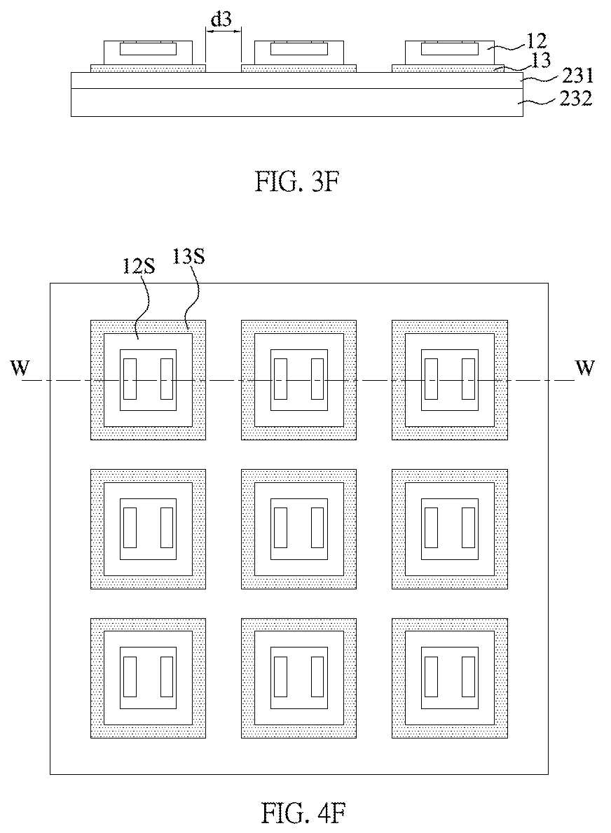

FIGS. 3A˜3E are cross-sectional views of making a light-emitting devices in accordance with an embodiment of the present disclosure. FIGS. 4A˜4E are top views of FIGS. 3A˜3E, respectively.

As shown in FIGS. 3A and 4A, a plurality of light-emitting chips 11 is disposed on a first temporary substrate 20, and two pads 111 of each of the light-emitting chip 11 are attached to the first temporary substrate 20. The first temporary substrate 20 includes an adhesion layer 201 and a supporting layer 202.

As shown in FIGS. 3B and 4B, a first light-transmitting layer 12 is formed to enclose the light-emitting chips 11.

As shown in FIGS. 3C and 4C, a first reflective layer 13 is formed on a top surface 121 of the first light-transmitting layer 12 without covering side surface 122 of the light-transmitting layer 12.

As shown in FIGS. 3D, 3E, 4D, and 4E, a second temporary substrate 23 including an adhesion layer 231 and a supporting layer 232 is attached to the first reflective layer 13 and the first temporary substrate 20 is removed to expose the pads 111. Thereafter, a first cutting step is performed to cut the light-transmitting layer 11 along cutting lines (L) until the first reflective layer 13 is exposed. In this step, the first light-transmitting layer 12 is divided into a plurality of light-transmitting segments 12S. In addition, the first reflective layer 13 is not to be cut and is a continuous layer. The light-transmitting segments are separated from each other by a second distance (d2).

As shown in FIGS. 3F, and 4F, a second cutting step is performed to cut the first reflective layer 13 to form a plurality of reflective segments 13S. The reflective segments 13S are separated from each other by a third distance (d3). The third distance (d3) is smaller than the second distance (d2).

After removing the second temporary substrate 23, a plurality of light-emitting devices 200 is formed.

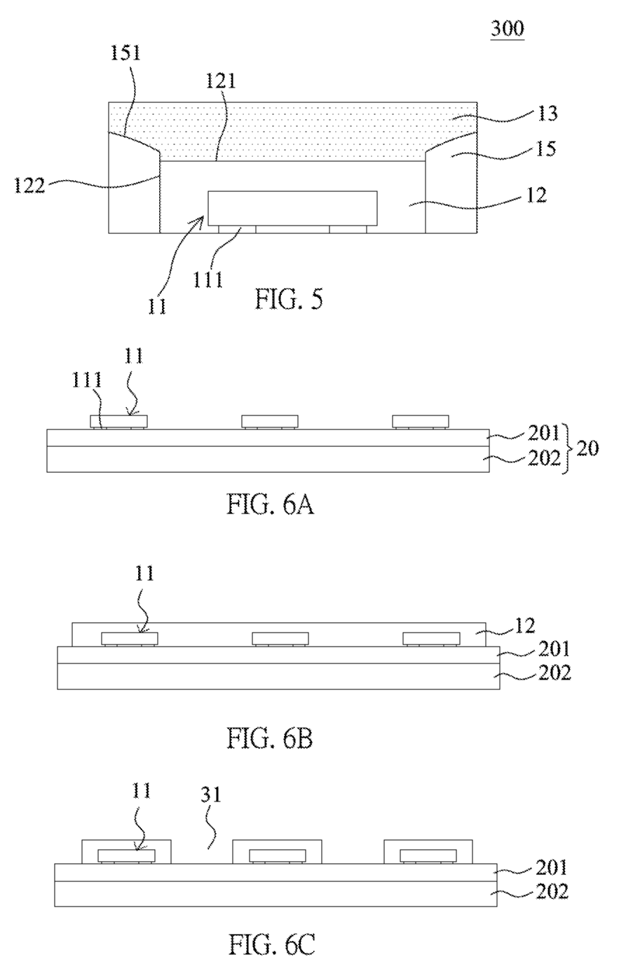

FIG. 5 is a cross-sectional view of a light-emitting device 300 in accordance with an embodiment of the present disclosure. The light-emitting device 200 includes a light-emitting chip 11, a first light-transmitting layer 12 enclosing the light-emitting chip 11, a second light-transmitting layer 15 covering the side surfaces 122 and having a curved top surface 151, and a first reflective layer 13 formed on a top surface 121 and the curved top surface 151. The second light-transmitting layer 15 is provided to improve the structural strength. The first light-transmitting layer 15 has a refractive index the same as or different from the second light-transmitting layer 15. When the second light-transmitting layer 15 has a refractive index smaller than the first light-transmitting layer 12, a luminous flux of the light-emitting deice 200 can be enhanced.

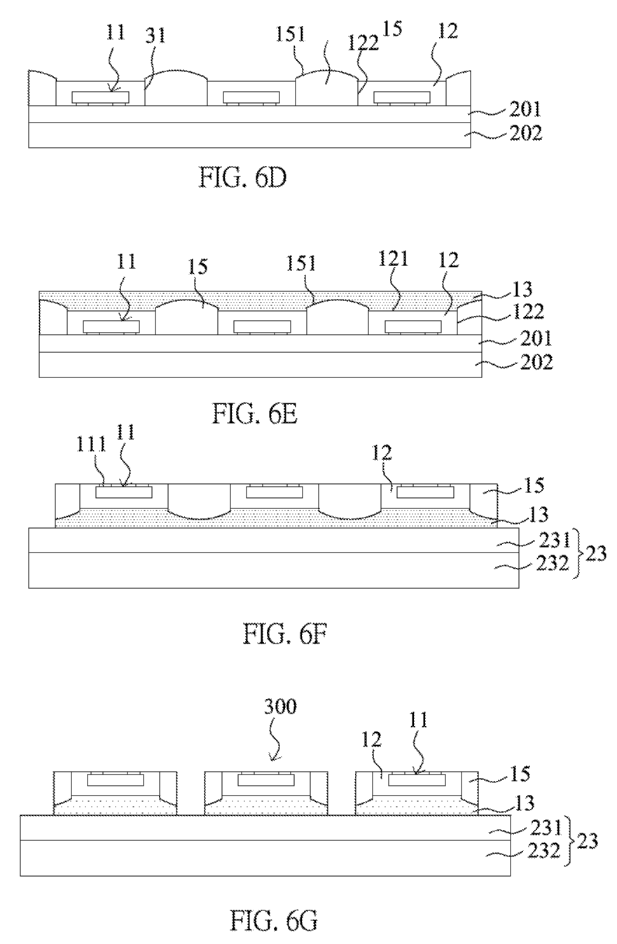

FIGS. 6A˜6F are cross-sectional views of making a light-emitting device 300 in accordance with an embodiment of the present disclosure.

As shown in FIG. 6A, a plurality of light-emitting chips 11 is disposed on a first temporary substrate 20, and two pads 111 of each of the light-emitting chips are attached to the first temporary substrate 20. The first temporary substrate 20 includes an adhesion layer 201 and a supporting layer 202.

As shown in FIG. 6B, a first light-transmitting layer 12 is formed to enclose the light-emitting chips 11.

As shown in FIG. 6C, a first cutting step is performed to cut the first light-transmitting layer 12 along cutting lines (not shown) until the adhesion layer 201 is exposed and a plurality of trenches 31 is formed.

As shown in FIG. 6D, a second light-transmitting layer 15 is filled into the trenches 31 and covers the side surface 122 of the light-transmitting layer 12. The second light-transmitting layer 15 has a height greater than the first light-transmitting layer 12 and has a convex top surface 151 which is formed during manufacturing process.

As shown in FIG. 6E, a first reflective layer 13 is formed on the first light-transmitting layer 12 and the second light-transmitting layer 15 to cover top surfaces 121, 151 thereof. The first reflective layer 13 does not cover the side surface 122 of the light-transmitting layer 12.

As shown in FIG. 6F, a second temporary substrate 23 including an adhesion layer 231 and a supporting layer 232 is attached to the first reflective layer 13, and the first temporary substrate 20 is removed to expose the pads 111. Thereafter, as shown in FIG. 6G, a second cutting step is performed to cut the first light-transmitting layer 12, the second light-transmitting layer 15 and the first reflective layer 13.

After removing the second temporary substrate 23, a plurality of light-emitting devices 300 is formed.

FIGS. 7A-7C are cross-sectional views showing the light-emitting devices 200 mounted on carriers with various reflection characteristics through an adhesive including a plurality of solder particles mixing with an epoxy resin (for example, Self Assembly Anisotropic Conductive Paste) in accordance with embodiments of the present disclosure. In brief, the adhesive is formed on the carrier and the light-emitting device 200 is disposed on the adhesive. Subsequently, the adhesive is subjected to a heat treatment to make the plurality of solder particles to aggregate to form an integral solder 116 and the epoxy resin 120 surrounding the integral solder 116. The light-emitting devices 200 is designed to have the minimum angle (θₘ) of 50°.

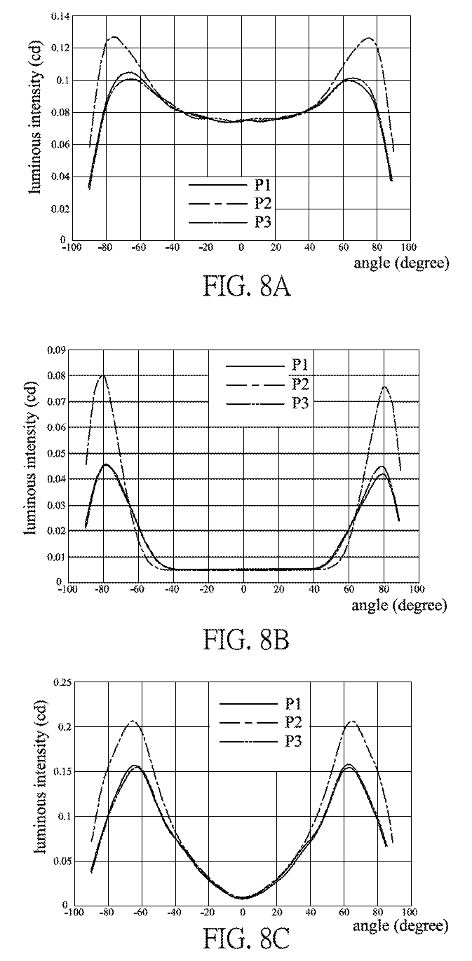

FIG. 7A is a cross-sectional view showing the light-emitting device 200 on a first carrier 61 with a diffuse-reflection surface. FIG. 8A shows a simulation result (using Trace Pro V7.1 software from Lambda Research Corporation) of a relationship curve between luminous intensity and angle in a Cartesian coordinate system (x coordinate represents angle; y coordinate represents luminous intensity) measured from the circle P1, P2, and P3 of the structure of FIG. 7A. The circle P1, P2, and P3 can be referred to FIGS. 1D-1F.

When light R1 from the light-emitting device 200 emits upwardly toward the first reflective layer 13, most light is absorbed or reflected by the first reflective layer 13, and there is little light directly passing through the first reflective layer 13. When the light enters into the reflective layer 13 and may be scattered by the reflective particles, some light (R11) will exit the light-emitting device 200 at an angle less than 50° (for example, θ₁=30°) which contributes to the luminous intensity in FIG. 8A at an angle less than 50° (for example, at 30° in circle P1, P2 or P3), and some light (R12) will exit the light-emitting device 200 at an angle (for example, θ₂=80°) larger than 50° which contributes to the luminous intensity in FIG. 8A at an angle larger than 50° (for example, at 80° in circle P1, P2 or P3).

When light R2 is reflected by the first reflective layer 13 toward the first carrier 61, since the first carrier 61 has a diffuse-reflection surface, the light R2 is reflected at many angles, some of which (R21) contributes to the luminous intensity at the angle less than 50° and some of which (R22) contributes to the luminous intensity at the angle larger than 50°. Therefore, the difference between the luminous intensity at the angle less than 50° and the luminous intensity at the angle larger than 50° is small. A ratio of the luminous intensity at the angle of 0° to that at the angle of 80° is larger than 0.5 and a ratio of the luminous intensity at the angle of 50° to that at the angle of 80° is larger than 0.7.

Light R3 does not touch the first reflective layer 13 and directly emits out of the light-emitting device 200 and contribute to the luminous intensity at the angle not less than 50°. The diffuse-reflection surface is formed by coating a material with a plurality of reflective particles dispersed therein.

FIG. 7B is a cross-sectional view showing a light-emitting device 200 on a second carrier 62 with a light-absorbing surface in accordance with an embodiment of the present disclosure. FIG. 8B shows a simulation result of a relationship curve between luminous intensity and angle in a Cartesian coordinate system (x coordinate represents angle; y coordinate represents luminous intensity) measured from the circle P1, P2, and P3 of FIG. 7B. The circle P1, P2, and P3 can be referred to FIGS. 1D-1F.

Likewise, most light R1 is absorbed or reflected by the first reflective layer 13, and there is little light directly passing through the first reflective layer 13 for contributing to the luminous intensity at the angle less than 50° or not less than 50°. Different from the first carrier 61, the light (for example, R2) reflected by the first reflective layer 13 toward the second carrier 62 is absorbed by the second carrier 62 having a light-absorbing surface. Therefore, the light (for example, R2) reflected by the first reflective layer 13 toward the second carrier 62 does not contribute to the luminous intensity at the angle less than 50°. The luminous intensity at the angle less than 50° is lower and not equal to zero. A ratio of the luminous intensity at the angle of 0° (or 50°) to that at the angle of 80° is less than 0.2.

FIG. 7C is a cross-sectional view showing a light-emitting device on a third carrier 63 with a specular-reflection surface in accordance with an embodiment of the present disclosure. FIG. 8C shows a simulation result of a relationship curve between luminous intensity and angle in a Cartesian coordinate system (x coordinate represents angle; y coordinate represents luminous intensity) measured from the circle P1, P2, and P3 of FIG. 7C. The circle P1, P2, and P3 can be referred to FIGS. 1D-1F.

Likewise, most light R1 is absorbed or reflected by the first reflective layer 13, and there is little light directly passing through the first reflective layer 13 for contributing to the luminous intensity at the angle less than 50° or not less than 50°. Similar to the first carrier 61, the light reflected by the first reflective layer 13 toward the third carrier 63 is reflected by the third carrier 63 but at one angle. For example, the light (R2) is reflected by the third carrier 63 at an angle larger than 50°, which contributes to the luminous intensity at the angle larger than 50 and the light (R4) is reflected by the third carrier 63 at an angle less than 50° which contributes to the luminous intensity at the angle less than 50. Therefore, the luminous intensity at the angle less than 50° is not quite low. A ratio of the luminous intensity at the angle of 0° to that at the angle of 80° is less than 0.1 and the ratio of the luminous intensity at the angle of 50° to that at the angle of 80° is larger than 0.5. The specular-reflection surface is formed by coating a metal material such as silver or aluminum.

Compared to the luminous intensity at the angle less than 50° of FIGS. 8A, 8B, and 8C, the light-emitting device 200 formed on the second carrier 62 with a light-absorbing surface has a lowest luminous intensity and the light-emitting device 200 formed on the first carrier 61 with the diffuse-reflection surface has a highest luminous intensity. In addition, since most light are absorbed by the first carrier 62, the maximum value of the luminous intensity of FIG. 8B is lowest. Furthermore, the light-emitting device 200 is formed on the third carrier 63 with a specular-reflection surface has a higher luminous intensity at the angle of 50˜80°.

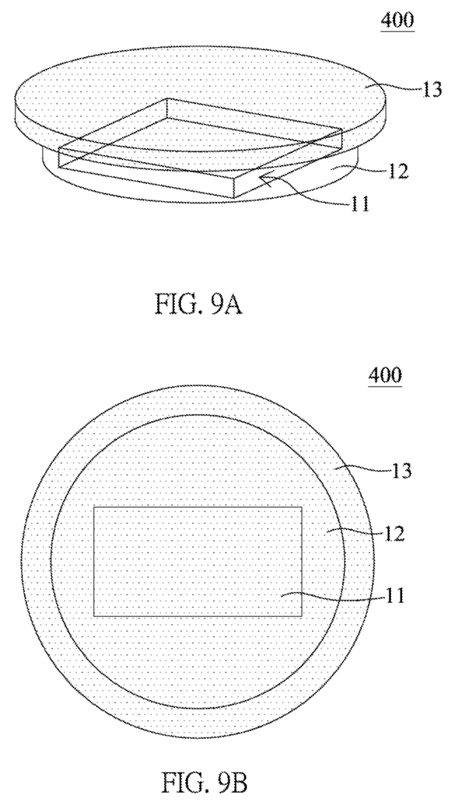

FIG. 9A is a perspective view of a light-emitting device 400 in accordance with an embodiment of the present disclosure. FIG. 9B is a top view of FIG. 9A. For clarification, a light-emitting chip 11 in FIG. 9A is drawn in solid line and every layer of FIG. 9B is drawn in solid line regardless of its material being non-transparent, transparent, or semi-transparent. The light-emitting device 400 includes a light-emitting chip 11, a first light-transmitting layer 12 enclosing the light-emitting chip 11, and a first reflective layer 13 formed on a top surface 121 of the first light-transmitting layer 12. The first light-transmitting layer 12 and the first reflective layer 13 are in a shape of circle. Compared to FIG. 2A where the first light-transmitting layer 12 and the first reflective layer 13 are in a shape of rectangle, the light-emitting device 400 is configured to produce a more uniform illumination distribution. A cross-sectional view of the light-emitting device 400 can be referred to FIG. 2B and related descriptions can be referred to the corresponding paragraphs of the light-emitting device 200.

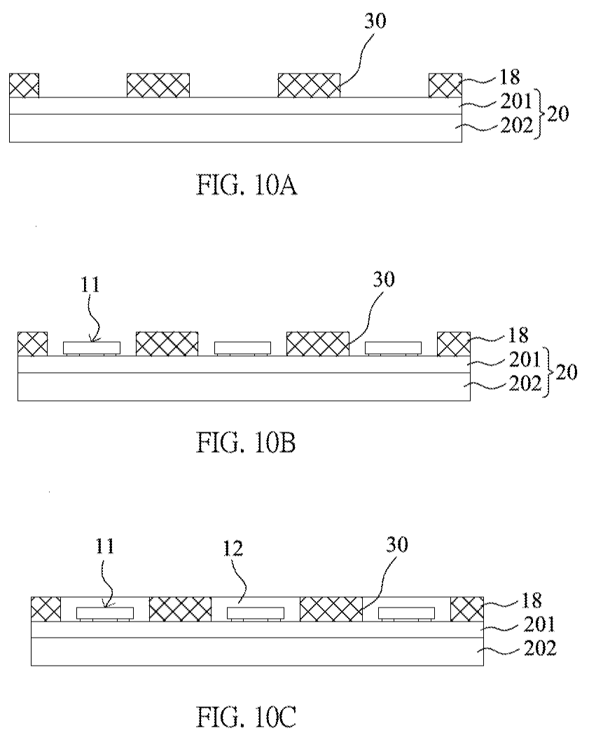

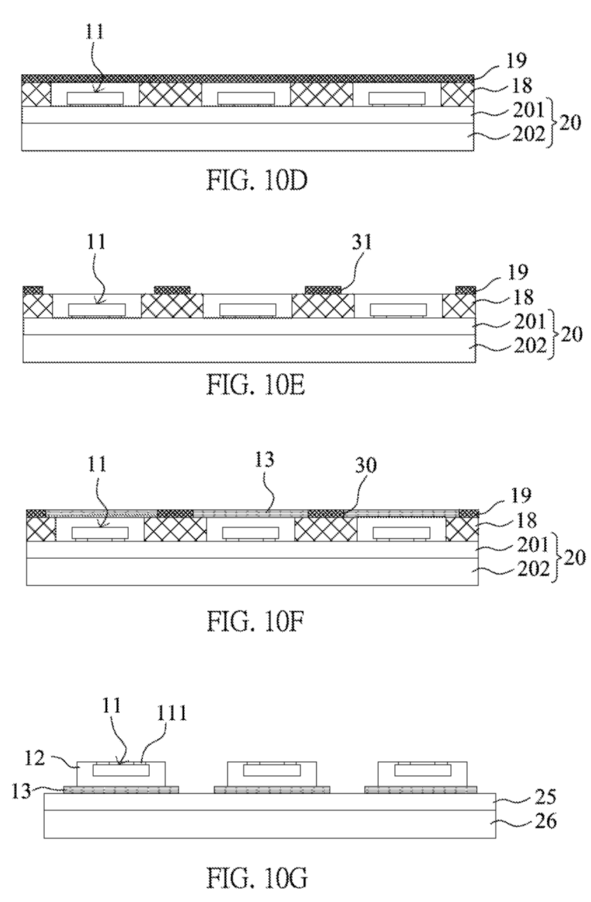

FIGS. 10A˜10G show cross-sectional views of making a light-emitting device 400 in accordance with an embodiment of the present disclosure.

As shown in FIG. 10A, a first photoresist layer 18 is formed on a first temporary substrate 20 including an adhesion layer 201 and a supporting layer 202. A photolithography process is performed to form a plurality of cylindrical-shape recesses 30 in the first photoresist layer 18.

As shown in FIG. 10B, a plurality of light-emitting chips 11 is disposed in the first cylindrical-shape recesses 30. In this embodiment, one light-emitting chip 11 is disposed in one recess 30. In other embodiment, two or more light-emitting chips 11 can be disposed in one recess 30.

As shown in FIG. 10C, a first light-transmitting layer 12 is filled into the recesses 30 to cover the light-emitting chips 11.

As shown in FIG. 10D, a second photoresist layer 19 is formed on the first light-transmitting layer 12 and the first photoresist layer 18.

As shown in FIG. 10E, a photolithography process is performed to form a plurality of second cylindrical-shape recesses 31 in the second photoresist layer 19.

As shown in FIG. 10F, a first reflective layer 13 is filled into the second recesses 31 to form on the light-transmitting layer 12.

As shown in FIG. 10G, a second temporary substrate 23 including an adhesion layer 231 and a supporting layer 232 is attached to the first reflective layer 13 and the first temporary substrate 20 is removed to expose the pads 111. Thereafter, an etching process is conducted to remove the first photoresist layer 18 and the second photoresist layer 19. Since the first photoresist layer 18 and the second photoresist layer 19 comprises the same material, they are removed simultaneously.

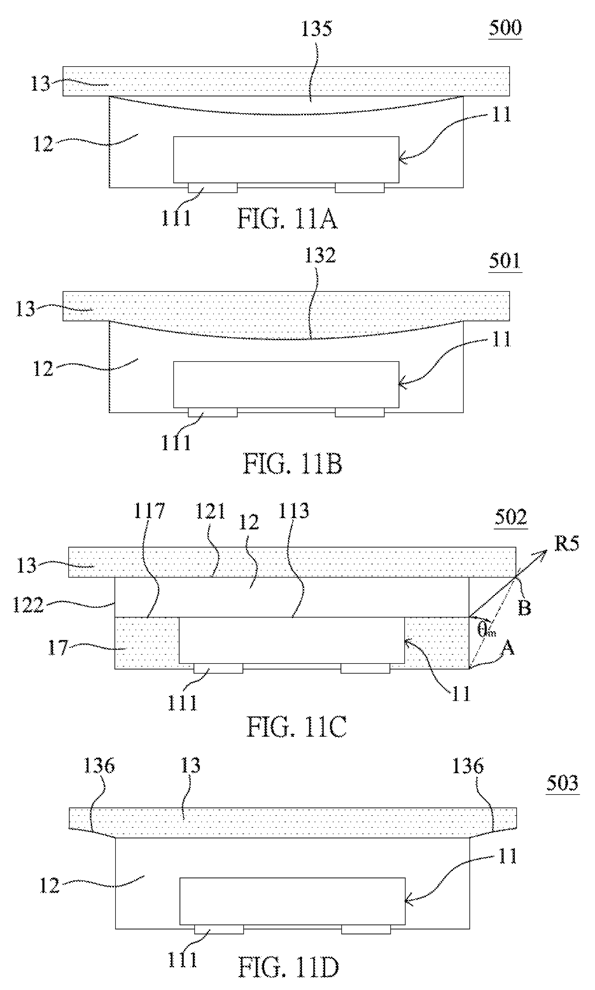

FIG. 11A is a cross-sectional view showing the light-emitting device 500 in accordance with an embodiment of the present disclosure. The light-emitting device 500 has a structure similar to the light-emitting device 200, and devices or elements with similar or the same symbols represent those with the same or similar functions. An air gap 135 is formed between the first reflective layer 13 and the first light-transmitting layer 12. As air has an refractive index lower than that of the first light-transmitting layer 12, a total internal reflection may occur at the boundary between the first light-transmitting layer 12 and air gap 135 for improving luminous intensity at the angle larger than the minimum angle (θₘ) and enhancing luminous flux. In addition, the first reflective layer 13 is provided for reflecting some light passing through the air gap 135 for reducing the luminous intensity at the angle less than the minimum angle (θₘ).

FIG. 11B is a cross-sectional view showing the light-emitting device 501 in accordance with an embodiment of the present disclosure. The light-emitting device 501 has a structure similar to the light-emitting device 500, and devices or elements with similar or the same symbols represent those with the same or similar functions. There is no air gap between the first reflective layer 13 and the light-transmitting layer 12. The first reflective layer 13 has a curved bottom surface 132 for enhancing luminous flux.

FIG. 11C is a cross-sectional view showing the light-emitting device 502 in accordance with an embodiment of the present disclosure. The light-emitting device 502 has a structure similar to the light-emitting device 200, and devices or elements with similar or the same symbols represent those with the same or similar functions. A second reflective layer 17 is provided to surround the light-emitting chip 11 without covering the top surface 113 of the light-emitting chip 11. The first light-transmitting layer 12 covers the top surface 113 and a top surface 117 of the second reflective layer 17. The first reflective layer 13 is formed on the top surface 121 of the light-transmitting layer 12. Because of the second reflective layer 17, most light emitted from the light-emitting chip 11 will exit the light-emitting device 502 through the side surface 122 (the interface between the first light-transmitting layer 12 and the ambient environment (for example, air)) which is above point A so light (for example, R5) will exit the light-emitting device 502 at an angle larger than θₘ, thereby for enhancing luminous intensity at the angle larger than θₘ.

FIG. 11D is a cross-sectional view showing the light-emitting device 503 in accordance with an embodiment of the present disclosure. The light-emitting device 502 has a structure similar to the light-emitting device 200, and devices or elements with similar or the same symbols represent those with the same or similar functions. The firs reflective layer 13 has a curved surface 136 for enhancing luminous flux.

FIG. 11E is a cross-sectional view showing the light-emitting device 504 in accordance with an embodiment of the present disclosure. The light-emitting device 502 has a structure similar to the light-emitting device 200, and devices or elements with similar or the same symbols represent those with the same or similar functions. The firs reflective layer 13 has a curved surface 136 for enhancing luminous flux. Different from the light-emitting device 503 in FIG. 11D, the first light-transmitting layer 12 has a side surface flush with a side surface of the first light reflective layer 13.

FIG. 11F is a cross-sectional view showing the light-emitting device 505 in accordance with an embodiment of the present disclosure. The light-emitting device 502 has a structure similar to the light-emitting device 200, and devices or elements with similar or the same symbols represent those with the same or similar functions. The firs reflective layer 13 has a curved surface 136 for enhancing luminous flux and a flat surface 138 extending from the curved surface 136 in a direction away from the light-emitting chip 11.

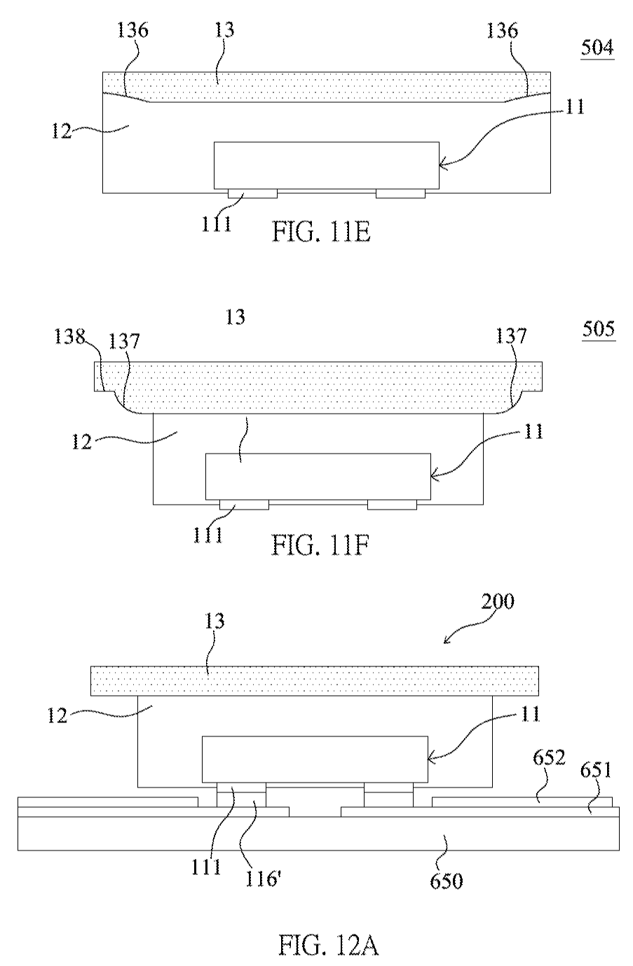

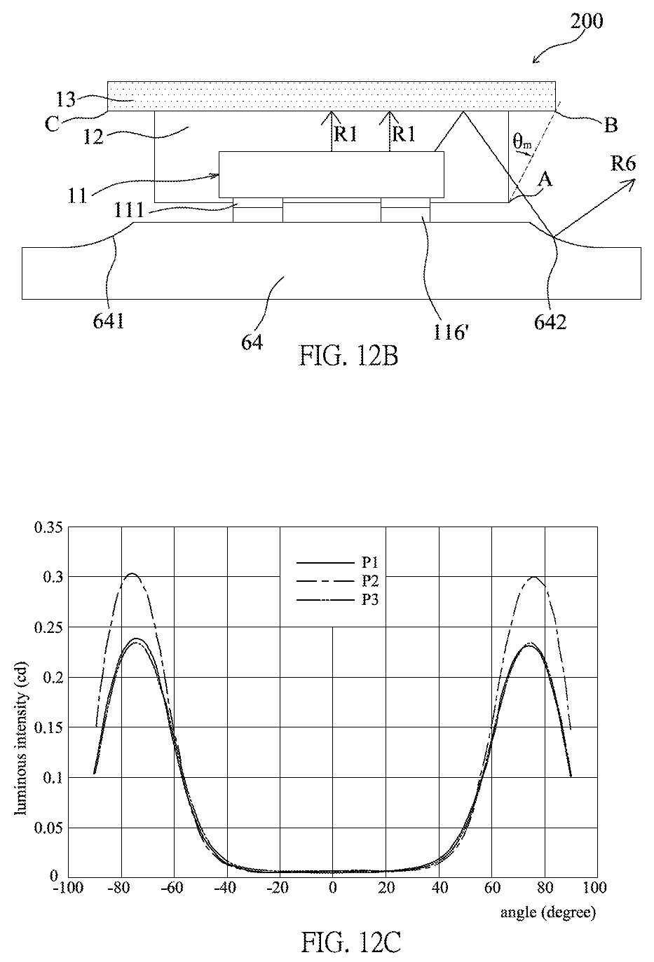

FIG. 12A is a cross-sectional view showing the light-emitting device 200 on a composite carrier in accordance with an embodiment of the present disclosure. The composite carrier include a fourth carrier 650, a first layer 651 formed on the fourth carrier 650, and a second layer 652 optionally formed on the first layer 651. The first layer 651 is used for reflecting light and electrically bonding to the light-emitting device 200 through solder 116′ and made of Ag, Au, Cu, Pt or Sn for providing a specular-reflection surface. Alternatively, a Al layer can be formed on the first layer 651 or between the first layer 651 and the second layer 652 for protecting the first layer 651 from deterioration by environment (for example, oxidation or sulfurization) and for providing the specular-reflection surface. The second layer 652 is light-transmitting for light toward the first layer 651 or reflected by the first layer 651 to pass therethrough. The second layer 652 includes SiO₂, SiN, AlN, or Al₂O₃.

FIG. 12B is a cross-sectional view showing the light-emitting device 200 on a fifth carrier 64 with two parabolic surfaces 641, 642 through solder 116′ in accordance with an embodiment of the present disclosure. In this embodiment, the focus of the parabolic surfaces 641, 642 is located at point C and point B and the vertex of the parabolic surfaces 641 is located at point A. The line connecting point A and point B is axis of symmetry. When light is incident on the parabolic surfaces 641, 642, it will be reflected at an angle not less than the minimum angle (θₘ). In other words, there will no light with an angle less than the minimum angle (θₘ) exiting the light-emitting device 200 when hitting the parabolic surfaces 641, 642. The light-emitting devices 200 is designed to have the minimum angle (θₘ) of 50°.

FIG. 12C shows a simulation result of a relationship curve between luminous intensity and angle in a Cartesian coordinate system (x coordinate represents angle; y coordinate represents luminous intensity) measured from the circle P1, P2, and P3 of FIG. 12B. The circle P1, P2, and P3 can be referred to FIGS. 1D˜1F.

Similar to FIGS. 7A and 8A, most light R1 is absorbed or reflected by the first reflective layer 13, and there is little light directly passing through the first reflective layer 13 for contributing to the luminous intensity at the angle less than 50° or not less than 50°. The light (for example, R6) reflected by the parabolic surfaces 641, 642 will contribute to the luminous intensity at the angle not less than 50°. Accordingly, the luminous intensity at the angle less than 50° is lower and not equal to zero. A ratio of the luminous intensity at the angle of 0° to that at the angle of 80° is less than 0.3. A ratio of the luminous intensity at the angle of 0° to that at the angle of 50° is less than 0.2

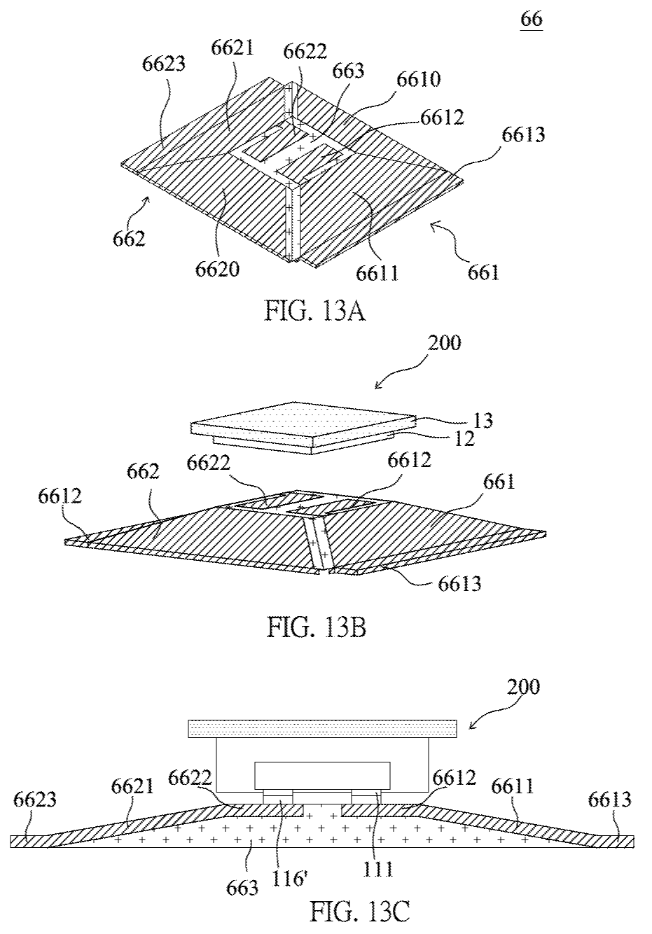

FIG. 13A is a perspective view of a lead frame 66 in accordance with an embodiment of the present disclosure. FIG. 13B is an exploded view of the light-emitting device 200 mounted on the lead frame 66 in accordance with an embodiment of the present disclosure. FIG. 13C is a cross-sectional view of the light-emitting device 200 mounted on the lead frame 66 in accordance with an embodiment of the present disclosure.

In this embodiment, the lead frame 66 includes a first electrode plate 661 and a second electrode plate 662 which is physically separated from the first electrode plate 661. Each of the first electrode plate 661 and the second electrode plate 662 includes a first part 6610, 6620, and a second part 6611, 6621, a third part 6612, 6622, and a fourth part 6613, 6623.

The first part 6610 (6620) and the second part 6611 (6621) are inclined with respect to the third part 6612 (6622). The fourth part 6613 (6623) extends from the second part 6611 (6621) in a direction away from the third part 6612 (6622). The fourth parts 6613, 6623 are used for mounting the lead frame 66 on another carrier (not shown) by solder (not shown). The third parts 6612, 6622 are used for mounting the light-emitting device 200 thereon. Specifically, the pads 111 (shown in FIG. 2B) of the light-emitting device 200 are connected to the third parts 6612, 6622 through solder (not shown), respectively. An insulative 663 is formed optionally between the first electrode plate 661 and the second electrode plate 662 for securely connecting the first electrode plate 661 with the second electrode plate 662. The first part 6610 (6620) and the second part 6611 (6621) provide parabolic-like reflective surfaces.

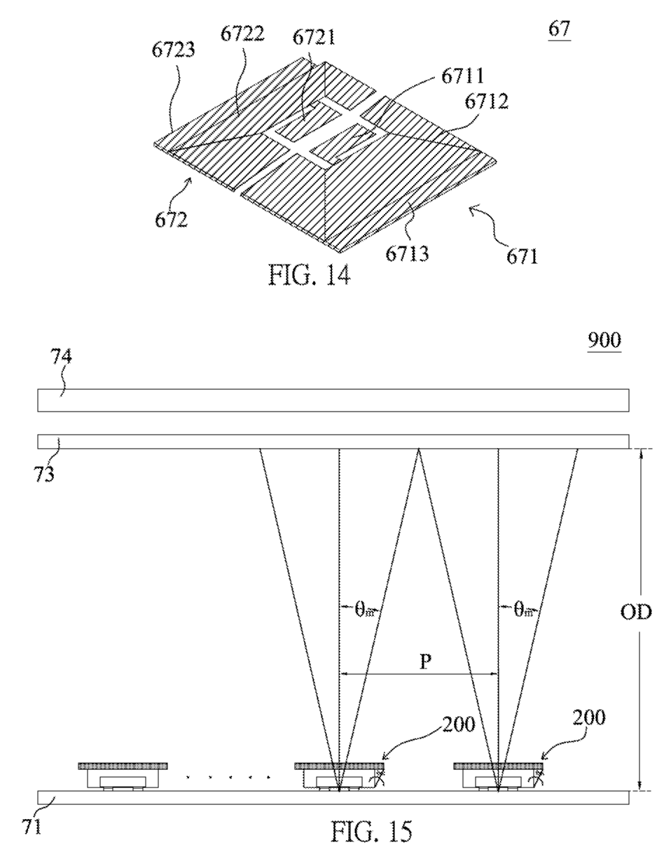

FIG. 14 is a perspective view of a lead frame 67 in accordance with an embodiment of the present disclosure. In this embodiment, the lead frame 67 includes a first electrode plate 671 and a second electrode plate 672 which is physically separated from the first electrode plate 671. Each of the first electrode plate 671 and the second electrode plate 672 includes a first part 6711, 6721, and a second part 6712, 6722, and a third part 6713, 6723.

Similar to the lead frame 66, the second part 6712 (6722) are inclined with respect to the first part 6711 (6721). The third part 6713 (6723) extends from the second part 6712 (6722) in a direction away from the first part 6711 (6721). The third part 6713 (6723) are used for mounting the lead frame 67 on another carrier (not shown) by solder (not shown). The first parts 6711, 6721 are used for mounting the light-emitting device 200 thereon. Specifically, the pads 111 (shown in FIG. 2B) of the light-emitting device 200 are connected to the first parts 6711, 6721 through solder (not shown), respectively. An insulative (not shown) is formed optionally between the first electrode plate 671 and the second electrode plate 672 for securely connecting the first electrode plate 671 with the second electrode plate 672. The second part 6712, 6722 provide parabolic-like reflective surfaces.

FIG. 14 shows a cross-sectional view of a direct-lit backlight display 900 in accordance with an embodiment of the present disclosure. The direct-lit backlight display 900 includes a plurality of light-emitting devices 200 disposed on a sixth carrier 71 in an array fashion, an optical unit 73, and a panel 74. The optical unit 73 can include a plurality of films, for example, diffuser film, brightness enhancement film etc. A brightness uniformity of a display is decided by various parameters such as pitch, optical distance (OD), the minimum angle (θₘ), and the features (for example, thickness) of the optical unit 73.

As shown in FIG. 14, the pitch (P) is defined as a distance between a central point of a light-emitting device 200 and a central point of adjacent light-emitting device 200. The optical distance is defined as a distance between a top surface of the sixth carrier 71 and the bottom surface of the optical unit 73. The optical distance, the pitch and the angle meet the equation II:

2*OD*tan θₘ=P (equation II)

Ideally, when the pitch is equal to 2*OD*tan θₘ, the entire bottom surface of the optical unit 73 can be emanated by the light-emitting devices 200 for obtaining a better brightness uniformity. In other embodiment, since the optical unit 73 can diffuse the light, the pitch can be designed to be larger than 2*OD*tan θₘ for manufacturing cost consideration. Alternatively, a lens can be provided to increase the pitch. For example, provided that the OD is 10 cm and the minimum angle (θₘ) is 40°, the pitch is 16.782 mm. Provided that the OD is 10 cm and the minimum angle (θₘ) is 50°, the pitch is 23.82 mm. Provided that the OD is 10 cm and the minimum angle (θₘ) is 60°, the pitch is 34.64 mm. Provided that the OD is 10 cm and the minimum angle (θₘ) is 70°, the pitch is 54.94 mm.

Generally speaking, the brightness uniformity is tested by dividing the display into nine areas and measuring the luminance (cd/m², nit) of the nine areas. When a ratio of the maximum luminance to the minimum luminance among the nine areas is less than 1%, better brightness uniformity can be obtained.

Likewise, the sixth carrier 71 can be one of the aforesaid carriers 61, 62, 63, or the composite carrier. The light-emitting device 200 can be replaced by the aforesaid light-emitting device 300, 400, 500˜505. Alternatively, the aforesaid light-emitting device can be mounted on the lead frame 66, 67, and then mounted on the carrier. The sixth carrier 71 can includes parabolic surfaces (as shown in FIG. 12B) corresponding to the respective light-emitting device for enhancing luminous intensity at the angle not less than the angle of θₘ.

The light-emitting chip includes a first-type semiconductor layer, an active layer, and a second-type semiconductor layer. When the aforesaid light-emitting unit has a hetero-structure, the first-type semiconductor layer and the second-type semiconductor layer, for example a cladding layer or a confinement layer, provide holes and electrons, respectively, and each type layer has a bandgap greater than that of the active layer, thereby increasing the probability of electrons and holes combining in the active layer to emit light. The first-type semiconductor layer, the active layer, and the second-type semiconductor layer can be made of III-V group semiconductor materials, such as AlₓIn_{y}Ga_{(1-x-y)}N or AlₓIn_{y}Ga_{(1-x-y)}P, wherein 0≤x, y≤1; (x+y)≤1. Depending on the material of the active layer, the light-emitting chip can emit a red light with a peak wavelength or dominant wavelength of 610˜650 nm, a green light with a peak wavelength or dominant wavelength of 530˜570 nm, a blue light with a peak wavelength or dominant wavelength of 450˜490 nm, a purple light with a peak wavelength or dominant wavelength of 400˜440 nm, a UV light with a peak wavelength of 200˜400 nm, or a light with a peak wavelength larger than 700 nm (for example, 850 nm, 940 nm, 1100 nm, or 1300 nm)

A plurality of wavelength-conversion particles can be optionally added into the first light-transmitting layer or/and the second light-transmitting layer. The wavelength-conversion particles have a particle size of 10 nm˜100 μm and include one or more kinds of inorganic phosphor, organic fluorescent colorants, semiconductors, or combinations thereof. The inorganic phosphor includes but is not limited to, yellow-greenish phosphor or red phosphor. The yellow-greenish phosphor comprises aluminum oxide (such as YAG or TAG), silicate, vanadate, alkaline-earth metal selenide, or metal nitride. The red phosphor includes fluoride (K₂TiF₆:Mn⁴⁺, K₂SiF₆:Mn⁴⁺), silicate, vanadate, alkaline-earth metal sulfide (CaS), metal nitride oxide, a mixture of tungstate and molybdate. The weight percentage (w/w) of the wavelength-conversion particles within the matrix is between 50%˜70%. The semiconductors include crystal with nano-sizes, for example, quantum dot. The quantum dot can be ZnS, ZnSe, ZnTe, ZnO, CdS, CdSe, CdTe, GaN, GaP, GaSe, GaSb, GaAs, AlN, AlP, AlAs, InP, InAs, Te, PbS, InSb, PbTe, PbSe, SbTe, ZnCdSeS, CuInS, CsPbCl₃, CsPbBr₃, or CsPbI₃.

The wavelength-conversion particles can absorb a first light emitted from the light-emitting chip 11 and convert the first light to a second light having a spectrum different from that of the first light. The first light is mixed with the second light to produce a third light. In this embodiment, the third light has chromaticity coordinates (x, y) on CIE 1931 chromaticity diagram, wherein 0.27≤x≤0.285; 0.23≤y≤0.26. In another embodiment, the first light is mixed with the second light to produce a third light, such as a white light. Based on the weight percentage and the material of the wavelength-conversion particles, the light-emitting device has a correlated color temperature of about 2200K˜6500K (ex. 2200K, 2400K, 2700K, 3000K, 5000K˜5700K, 6500K) under a thermal stable state with a color point (CIE x, y) within a seven-step MacAdam ellipse. In another embodiment, the first light is mixed with the second light to produce purple light, amber light, green light, yellow light or other non-white light.

The light-transmitting layer includes epoxy, silicone, PI, BCB, PFCB, Acrylic resin, PMMA, PET, PC or polyetherimide. The adhesion layer include a blue tape, thermal release sheet or tape, UV release tape or polyethylene terephthalate (PET). The supporting layer includes glass or sapphire for supporting the adhesion layers 201.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

1. A light emitting device comprising:
a light-emitting chip having a top surface and a bottom surface opposite to the top surface;
a pad disposed under the bottom surface;
a first light-transmitting layer formed on the light-emitting chip and having a plurality of side surfaces; and
a first reflective layer formed above the top surface of the light-emitting chip and extending beyond the plurality of side surfaces of the light-transmitting layer.

2. The light-emitting device of claim 1, further comprising a second light-transmitting layer covering the two side surfaces.

3. The light-emitting device of claim 2, wherein the first light-transmitting layer has a refractive index different from the second light-transmitting layer.

4. The light-emitting device of claim 3, wherein the second light-transmitting layer has a refractive index smaller than the first light-transmitting layer.

5. The light-emitting device of claim 1, further comprising an air gap between the first light-transmitting layer and the first reflective layer.

6. The light-emitting device of claim 1, further comprising a second reflective layer surrounding the light-emitting chip.

7. The light-emitting device of claim 6, wherein the first light-transmitting layer is formed on the second reflective layer.

8. The light-emitting device of claim 1, further comprising a carrier on which the light-emitting device is mounted having a diffuse-reflection surface.

9. The light-emitting device of claim 1, further comprising a carrier on which the light-emitting device is mounted having a specular-reflection surface.

10. The light-emitting device of claim 1, further comprising a carrier on which the light-emitting device is mounted having a light-absorbing surface.

11. The light-emitting device of claim 1, further comprising a carrier on which the light-emitting device is mounted having a parabolic surface.

12. The light-emitting device of claim 1, further a lead frame on which the light-emitting device is mounted having a first electrode plate and a second electrode plate separated from the first electrode plate.

13. A display comprising:
a plurality of light-emitting device of claim 1;
a optical unit; and
a panel.
